(19) United States
(12) Patent Application Publication
(10) Pub. No.: US 2023/0317565 A1
(43) Pub. Date: Oct. 5, 2023

(54) ELECTRONIC PACKAGE AND MANUFACTURING METHOD THEREOF

(71) Applicant: SILICONWARE PRECISION INDUSTRIES CO., LTD., Taichung City (TW)

(72) Inventors: Chung-Yu Ke, Taichung City (TW); Liang-Pin Chen, Taichung City (TW)

(73) Assignee: SILICONWARE PRECISION INDUSTRIES CO., LTD., Taichung City (TW)

(21) Appl. No.: 17/750,711

(22) Filed: May 23, 2022

(30) Foreign Application Priority Data
Mar. 29, 2022 (TW) 111111933

(51) Int. Cl. H01L 23/48; H01L 25/16; H01L 23/498; H01L 21/56; H01L 23/31

(52) U.S. Cl. CPC H01L 23/481; H01L 25/162; H01L 25/165; H01L 23/49822; H01L 24/32; H01L 21/565; H01L 23/3135; H01L 23/3128; H01L 23/49838

(57) ABSTRACT

An electronic package is provided, in which a first packaging layer is formed on a circuit structure, a portion of at least one conductive column is inserted into the first packaging layer, a remaining portion of the conductive column is protruded from the first packaging layer, and a second packaging layer is formed to cover the remaining portion of the conductive column, so that the conductive column is integrally formed in the first packaging layer and the second packaging layer. Therefore, the impact on the conductive column from the second packaging layer can be reduced and the problem of tilting of the conductive column can be prevented.

### BACKGROUND

### 1. Technical Field

The present disclosure relates to a semiconductor device, and more particularly, to an electronic package capable of improving reliability and a manufacturing method thereof.

### 2. Description of Related Art

With the evolution of semiconductor packaging technique, different packaging types have been developed for semiconductor devices, and in order to improve electrical functions and save packaging space, different three-dimensional packaging techniques have been developed to combine integrated circuits with different functions into a single package structure. For example, electronic elements (e.g., memory, central processor, graphics processor, image application processor, etc.) with different functions are integrated into a system by stacking design, so as to be applied to thin and light electronic products.

FIG. 1 is a schematic cross-sectional view of a conventional semiconductor package 1. As shown in FIG. 1, in a manufacturing method of the semiconductor package 1, a first semiconductor chip 11 and a plurality of conductive columns 13 are disposed on a circuit structure 10, then the first semiconductor chip 11 and the conductive columns 13 are covered by an encapsulant 15, and then a routing structure 14 is formed on the encapsulant 15, so that a second semiconductor chip 12 is disposed on the routing structure 14. The conductive columns 13 are electrically connected to the circuit structure 10 and the routing structure 14, the circuit structure 10 is electrically connected to the first semiconductor chip 11, the routing structure 14 is electrically connected to the second semiconductor chip 12, and a plurality of solder balls 19 are formed on a bottom side of the circuit structure 10 for attaching to a circuit board (not shown).

However, in the manufacturing method of the conventional semiconductor package 1, the conductive columns 13 are firstly formed by electroplating on the circuit structure 10, and then the conductive columns 13 are covered with the encapsulant 15. Therefore, the conductive columns 13 are easily impacted by the encapsulant 15 to be tilted or even broken. As a result, when the routing structure 14 is formed on the encapsulant 15, the conductive columns 13 cannot be effectively aligned, resulting in the ineffective electrical connection between the circuit structure 10 and the routing structure 14.

Therefore, how to overcome the aforementioned drawbacks of the prior art has become an urgent issue to be solved at present.

### SUMMARY

In view of the various shortcomings of the prior art, the present disclosure provides an electronic package, which comprises: a circuit structure; a first electronic element disposed on and electrically connected to the circuit structure; a first packaging layer disposed on the circuit structure and covering the first electronic element; at least one conductive column inserted into the first packaging layer and disposed on the circuit structure, wherein the conductive column is electrically connected to the circuit structure, and a portion of the conductive column is protruded from the first packaging layer; a second packaging layer disposed on the first packaging layer and covering the portion of the conductive column protruding from the first packaging layer, wherein an end surface of the conductive column is exposed from the second packaging layer; and a routing structure bonded on the second packaging layer and electrically connected to the conductive column.

The present disclosure also provides a manufacturing method for an electronic package, which comprises: disposing at least one first electronic element on a circuit structure, wherein the first electronic element is electrically connected to the circuit structure; forming a first packaging layer on the circuit structure, wherein the first electronic element is covered by the first packaging layer; forming at least one conductive column in the first packaging layer, wherein the conductive column is disposed on and electrically connected to the circuit structure, and a portion of the conductive column is protruded from the first packaging layer; forming a second packaging layer on the first packaging layer, wherein the second packaging layer covers the portion of the conductive column protruding from the first packaging layer, and an end surface of the conductive column is exposed from the second packaging layer; and forming a routing structure on the second packaging layer, wherein the routing structure is electrically connected to the conductive column.

In the aforementioned manufacturing method, a manufacturing process of the conductive column comprises: forming a barrier layer on the first packaging layer; forming a through hole communicating the barrier layer and the first packaging layer, wherein the circuit structure is exposed from the through hole; forming the conductive column in the through hole, wherein the conductive column is electrically connected to the circuit structure; and removing the barrier layer to enable a portion of the conductive column to be protruded from the first packaging layer.

In the aforementioned electronic package and manufacturing method thereof, the first electronic element and the first packaging layer are disposed on one side of the circuit structure, and at least one functional element is disposed on the other side of the circuit structure.

In the aforementioned electronic package and manufacturing method thereof, the circuit structure has a first ground layer, and the routing structure has a second ground layer, wherein the first ground layer and the second ground layer are electrically connected to the conductive column.

In the aforementioned electronic package and manufacturing method thereof, the first packaging layer and the second packaging layer are made with a same material.

In the aforementioned electronic package and manufacturing method thereof, the first packaging layer and the second packaging layer are made with different materials.

In the aforementioned electronic package and manufacturing method thereof, the first packaging layer has a hardness different from a hardness of the second packaging layer.

In the aforementioned electronic package and manufacturing method thereof, the present disclosure further comprises disposing at least one second electronic element on the routing structure, wherein the second electronic element is electrically connected to the routing structure.

As can be understood from the above, in the electronic package and manufacturing method thereof of the present disclosure, a first packaging layer is formed on the circuit structure, a portion of the conductive column is formed in the first packaging layer, a remaining portion of the conductive column is protruded from the first packaging layer, and the remaining portion of the conductive column is covered by the second packaging layer, such that the conductive column is integrally formed in the first packaging layer and the second packaging layer. Therefore, compared to the prior art, the present disclosure can reduce the impact on the conductive column from the second packaging layer, and prevent the conductive column from being tilted or broken. Thus, the conductive column can be effectively aligned when the routing structure is formed on the second packaging layer, so that the circuit structure and the routing structure can be effectively electrically connected.

### BRIEF DESCRIPTION OF THE DRAWINGS

FIG. 1 is a schematic cross-sectional view of a conventional semiconductor package.

FIG. 2A to FIG. 2G are schematic cross-sectional views illustrating a manufacturing method of an electronic package of the present disclosure.

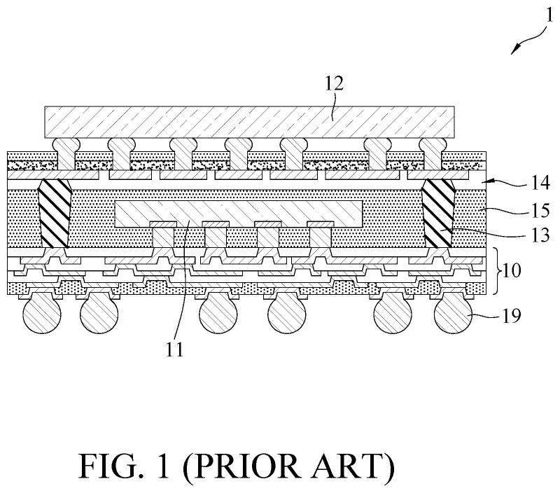

### DETAILED DESCRIPTION

Implementations of the present disclosure are illustrated using the following embodiments. One of ordinary skill in the art can readily appreciate other advantages and technical effects of the present disclosure upon reading the content of this specification.

It should be noted that the structures, ratios, sizes, etc. shown in the drawings appended to this specification are to be construed in conjunction with the disclosure of this specification in order to facilitate understanding of those skilled in the art. They are not meant to limit the implementations of the present disclosure, and therefore have no substantial technical meaning. Any modifications of the structures, changes of the ratio relationships or adjustments of the sizes, are to be construed as falling within the range covered by the technical content disclosed herein to the extent of not causing changes in the technical effects created and the objectives achieved by the present disclosure. Meanwhile, terms such as “on,” “first,” “second,” “a,” and the like recited herein are for illustrative purposes, and are not meant to limit the scope in which the present disclosure can be implemented. Any variations or modifications to their relative relationships, without changes in the substantial technical content, should also to be regarded as within the scope in which the present disclosure can be implemented.

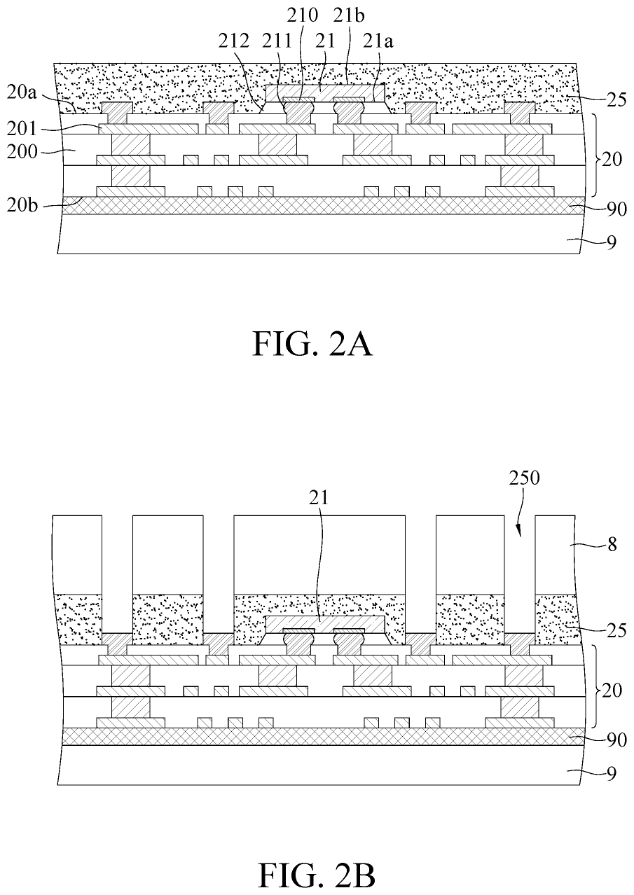

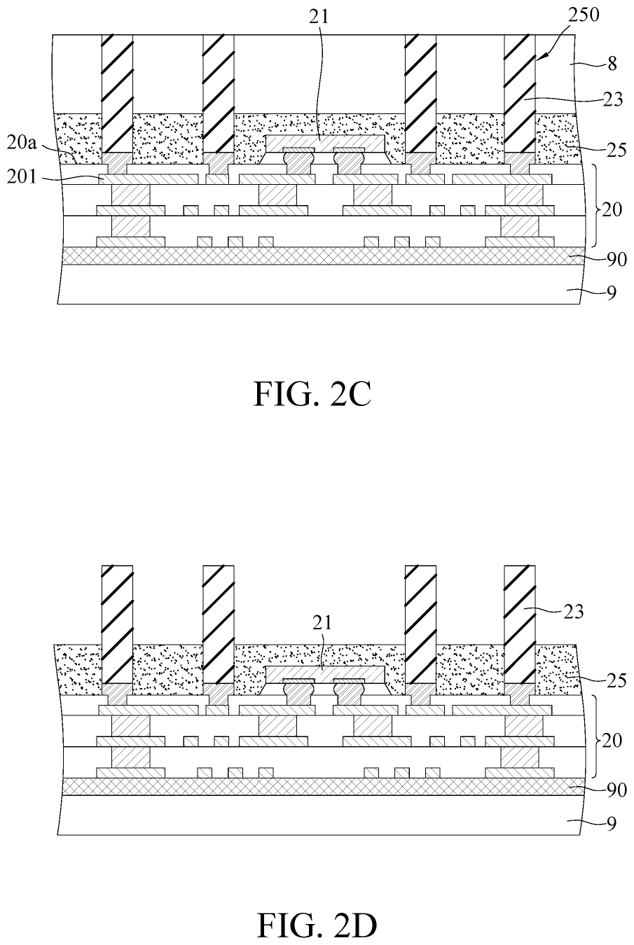

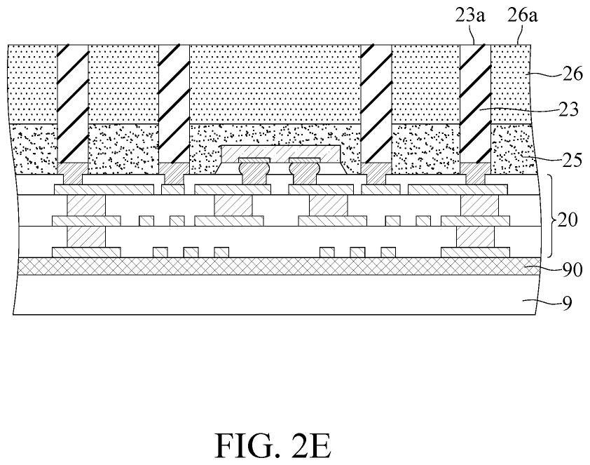

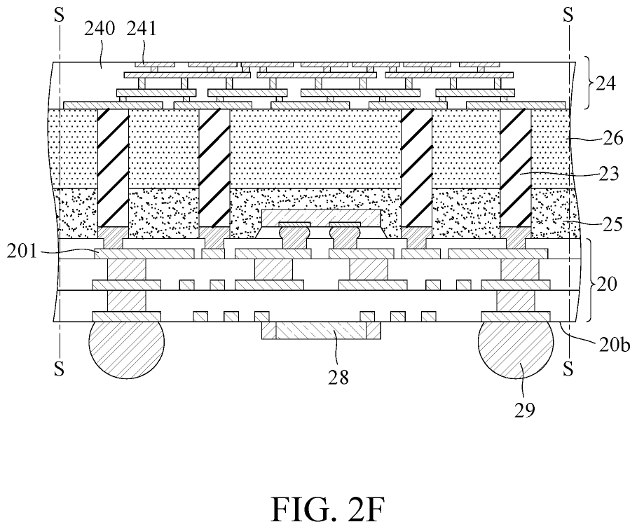

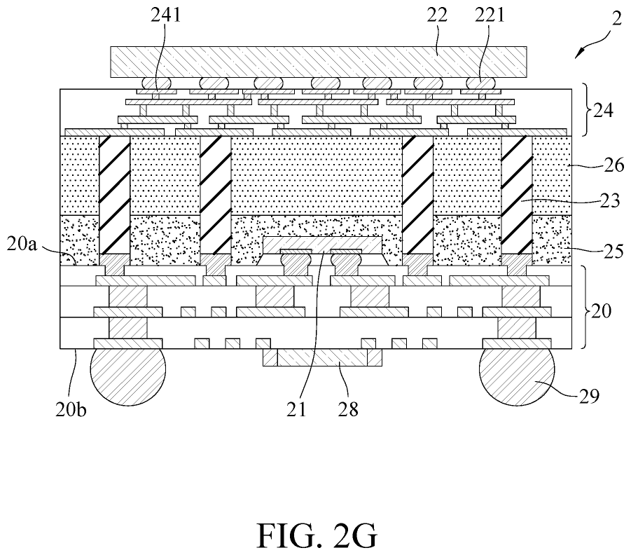

FIG. 2A to FIG. 2G are schematic cross-sectional views illustrating a manufacturing method of an electronic package 2 of the present disclosure.

As shown in FIG. 2A, a circuit structure 20 is formed on a carrier 9, the circuit structure 20 has a first side 20a and a second side 20b opposing to the first side 20a, such that at least one first electronic element 21 is disposed on the first side 20a of the circuit structure 20, and the first electronic element 21 is covered by a first packaging layer 25, so the circuit structure 20 is bonded to the carrier 9 with the second side 20b thereof.

In an embodiment, the circuit structure 20 is a package substrate with a core layer and a circuit layer, or a coreless substrate structure, the circuit structure 200 comprises at least one dielectric layer 200 and a circuit layer 201 bonded to the dielectric layer 200. For instance, the coreless substrate structure is formed by a redistribution layer (RDL) manufacturing method, wherein the material for forming the circuit layer 201 is copper, and the material for forming the dielectric layer 200 is a dielectric material such as polybenzoxazole (PBO), polyimide (PI), prepreg (PP) and the like. It should be understood that the circuit structure 20 can also be other carrier plates, such as a silicon interposer, for carrying electronic elements such as chips and not limited to the above.

Moreover, the carrier 9 is, for example, a plate of semiconductor material (e.g., silicon or glass), and a release layer 90 is formed on the carrier 9, so that the circuit structure 20 is bonded on the release layer 90.

Further, the first electronic element 21 is an active element, a passive component, or a combination of the active element and the passive element, wherein the active element is for example a semiconductor chip, and the passive element is for example a resistor, a capacitor, or an inductor. In an embodiment, the first electronic element 21 is a semiconductor chip and has an active surface 21a and an inactive surface 21b opposing to the active surface 21a, and the active surface 21a has a plurality of electrode pads 210, so that the electronic element 21 is electrically connected to the circuit layer 201 via the electrode pads 210 thereof by means of flip-chip (shown as through a plurality of conductive bumps 211), and the plurality of conductive bumps 211 are covered by an underfill 212; alternatively, the first electronic element 21 can also be electrically connected to the circuit layer 201 via a plurality of bonding wires (not shown) by means of wire bonding; or the first electronic element 21 can directly contact the circuit layer 201 to be electrically connected to the circuit layer 201. However, the way in which the first electronic element 21 is electrically connected to the circuit layer 201 is not limited to the above.

In addition, the first packaging layer 25 is an insulation material such as polyimide (PI), dry film, encapsulant of epoxy resin, or molding compound, and the first packaging layer 25 can be formed on the first side 20a of the circuit structure 20 by means of lamination or molding. For example, the first packaging layer 25 covers the inactive surface 21b of the first electronic element 21; alternatively, a portion of the material of the first packaging layer 25 can be removed by a leveling process such as etching or grinding, such that the surface of upper side of the first packaging layer 25 is flush with the inactive surface 21b of the first electronic element 21.

As shown in FIG. 2B, a barrier layer 8 is formed on the first packaging layer 25, and at least one through hole 250 is formed to communicate the barrier layer 8 and the first packaging layer 25, so that the circuit layer 201 is exposed from the through hole 250.

As shown in FIG. 2C, a plurality of conductive columns 23 are formed in the through holes 250, so that the conductive columns 23 are electrically connected to the circuit layer 201 on the first side 20a of the circuit structure 20.

In an embodiment, the conductive columns 23 are metal pillars such as copper pillars or pillars made of other materials.

As shown in FIG. 2D, the barrier layer 8 is removed, so that the conductive columns 23 are protruded from the first packaging layer 25.

As shown in FIG. 2E, a second packaging layer 26 is formed on the first packaging layer 25, such that the second packaging layer 26 covers the conductive columns 23.

In an embodiment, the second packaging layer 26 is an insulation material such as polyimide, dry film, encapsulant of epoxy resin, or molding compound, and the second packaging layer 26 can be formed on the routing structure 24 by means of lamination or molding. It should be understood that the material for forming the second packaging layer 26 can be the same or different from the material of the first packaging layer 25, for instance, the hardness of the first packaging layer 25 is different from (or greater than) the hardness of the second packaging layer 26.

Moreover, a portion of the material of the second packaging layer 26, even portions of the material of the conductive columns 23, can be removed by a leveling process such as etching or grinding, so that a surface 26a of upper side of the second packaging layer 26 is flush with end surfaces 23a of the conductive columns 23, such that the end surfaces 23a of the conductive columns 23 are exposed from the second packaging layer 26. Alternatively, holes can be formed on the surface of upper side of the second packaging layer 26, such that the end surfaces 23a of the conductive columns 23 are exposed from the holes of the second packaging layer 26.

As shown in FIG. 2F, a routing structure 24 is formed on the second packaging layer 26, so that the routing structure 24 is electrically connected to the conductive columns 23. The carrier 9 and the release layer 90 are then removed to expose the second side 20b of the circuit structure 20.

In an embodiment, the routing structure 24 is a package substrate with a core layer and a circuit layer, or a coreless substrate structure, and the routing structure 24 comprises at least one insulation layer 240 and a routing layer 241 bonded to the insulation layer 240 and electrically connected to the conductive columns 23. For instance, the coreless substrate structure is formed by a redistribution layer (RDL) manufacturing method, wherein the material for forming the routing layer 241 is copper, and the material for forming the insulation layer 240 is a dielectric material such as polybenzoxazole (PBO), polyimide (PI), prepreg (PP) and the like.

Furthermore, the conductive columns 23 are electrically connected to the circuit layer 201 of the circuit structure 20 and the routing layer 241 of the routing structure 24, thus a portion of the circuit layer 201 of the circuit structure 20 can be used as a first ground layer, and a portion of the routing layer 241 of the routing structure 24 can be used as a second ground layer, such that the first ground layer and the second ground layer are electrically connected to the conductive columns 23.

Additionally, a ball placement process can be performed on the second side 20b of the circuit structure 20 to form a plurality of conductive elements 29 such as solder balls for subsequent connection to a circuit board (not shown). Further, a functional element 28 such as a passive element can also be arranged on the second side 20b of the circuit structure 20.

As shown in FIG. 2G, a second electronic element 22 is disposed on the routing structure 24, and then a singulation process is performed along cutting paths S shown in FIG. 2F to obtain the required electronic package 2.

In an embodiment, the second electronic element 22 is an active element, a passive element, or a combination of the active element and the passive element, wherein the active element is for example a semiconductor chip, and the passive element is for example a resistor, a capacitor, or an inductor. In an embodiment, the second electronic element 22 is a semiconductor chip and is electrically connected to the routing layer 241 by means of flip-chip (shown as through a plurality of conductive bumps 221); alternatively, the second electronic element 22 can also be electrically connected to the routing layer 241 via a plurality of bonding wires (not shown) by means of wire bonding; or the second electronic element 22 can directly contact the routing layer 241 to be electrically connected to the routing layer 241. However, the way in which the second electronic element 22 is electrically connected to the routing layer 241 is not limited to the above.

Therefore, in the manufacturing method of the present disclosure, a first packaging layer 25 is formed on the circuit structure 20 first, and then portions of the columns of the conductive columns 23 are formed in the first packaging layer 25, so the remaining columns of the conductive columns 23 are protruded from the first packaging layer 25, then the remaining columns of the conductive columns 23 are covered by the second packaging layer 26, so that the conductive columns 23 are integrally formed in the first packaging layer 25 and the second packaging layer 26. Thus, compared to the prior art, the manufacturing method of the present disclosure can reduce the impact on the conductive columns 23 from the second packaging layer 26, thereby preventing the problem of tilting or breaking of the conductive columns 23, so that the conductive columns 23 can be effectively aligned when the routing structure 24 is formed on the second packaging layer 26, such that the circuit structure 20 and the routing structure 24 can be effectively electrically connected.

On the other hand, by the hardness of the first packaging layer 25 being different from the hardness of the second packaging layer 26, the stress is dispersed. Therefore, when the second packaging layer 26 is bonded onto the first packaging layer 25, the stress of the routing structure 24 and the circuit structure 20 can be effectively dispersed to reduce stress concentration, thereby preventing the problem that the circuit layer 201 and the routing layer 241 can be broken due to the stress concentration.

The present disclosure also provides an electronic package 2, which comprises: a circuit structure 20, at least one first electronic element 21, a plurality of conductive columns 23, a first packaging layer 25, a second packaging layer 26, and a routing structure 24.

The first electronic element 21 is disposed on the circuit structure 20 and is electrically connected to the circuit structure 20.

The first packaging layer 25 is disposed on the circuit structure 20 and covers the first electronic element 21.

The conductive columns 23 are inserted into the first packaging layer 25 to be disposed on the circuit structure 20 and electrically connected to the circuit structure 20, such that portions of the conductive columns 23 are protruded from the first packaging layer 25.

The second packaging layer 26 is disposed on the first packaging layer 25 and covers portions of the conductive columns 23 protruding from the first packaging layer 25, such that end surfaces 23a of the conductive columns 23 are exposed from the second packaging layer 26.

The routing structure 24 is bonded on the second packaging layer 26 and is electrically connected to the conductive columns 23.

In an embodiment, the first electronic element 21 and the first packaging layer 25 are disposed on a first side 20a of the circuit structure 20, and at least one functional element 28 is disposed on a second side 20b of the circuit structure 20.

In an embodiment, the circuit structure 20 has a circuit layer 201 serving as a first ground layer, and the routing structure 24 has a routing layer 241 serving as a second ground layer, such that the first ground layer and the second ground layer are electrically connected to the conductive columns 23.

In an embodiment, the first packaging layer 25 and the second packaging layer 26 are made with the same material.

In an embodiment, the first packaging layer 25 and the second packaging layer 26 are made with different materials.

In an embodiment, a hardness of the first packaging layer 25 is different from a hardness of the second packaging layer 26.

In an embodiment, the electronic package 2 further comprises at least one second electronic element 22 disposed on the routing structure 24 and electrically connected to the routing structure 24.

To sum up, in the electronic package and the manufacturing method thereof of the present disclosure, the conductive columns are integrally formed in the first packaging layer and the second packaging layer, so that the impact on the conductive columns from the second packaging layer can be reduced, thereby preventing the conductive columns from being tilted or broken. Therefore, the conductive columns can be effectively aligned when the routing structure is formed on the second packaging layer, such that the circuit structure and the routing structure can be effectively electrically connected, thereby improving the reliability of the electronic package.

The above embodiments are set forth to illustrate the principles of the present disclosure, and should not be interpreted as to limit the present disclosure. The above embodiments can be modified by one of ordinary skill in the art without departing from the scope of the present disclosure as defined in the appended claims. Therefore, the scope of protection of the right of the present disclosure should be listed as the following appended claims.

What is claimed is:

1. An electronic package, comprising:
a circuit structure;
a first electronic element disposed on and electrically connected to the circuit structure;
a first packaging layer disposed on the circuit structure and covering the first electronic element;
at least one conductive column inserted into the first packaging layer and disposed on the circuit structure, wherein the conductive column is electrically connected to the circuit structure, and a portion of the conductive column is protruded from the first packaging layer;
a second packaging layer disposed on the first packaging layer and covering the portion of the conductive column protruding from the first packaging layer, wherein an end surface of the conductive column is exposed from the second packaging layer; and
a routing structure bonded on the second packaging layer and electrically connected to the conductive column.

2. The electronic package of claim 1, wherein the first electronic element and the first packaging layer are disposed on one side of the circuit structure, and at least one functional element is disposed on the other side of the circuit structure.

3. The electronic package of claim 1, wherein the circuit structure has a first ground layer, and the routing structure has a second ground layer, wherein the first ground layer and the second ground layer are electrically connected to the conductive column.

4. The electronic package of claim 1, wherein the first packaging layer and the second packaging layer are made with a same material.

5. The electronic package of claim 1, wherein the first packaging layer and the second packaging layer are made with different materials.

6. The electronic package of claim 1, wherein the first packaging layer has a hardness different from a hardness of the second packaging layer.

7. The electronic package of claim 1, further comprising at least one second electronic element disposed on and electrically connected to the routing structure.

8. A method for manufacturing an electronic package, comprising:
disposing at least one first electronic element on a circuit structure, wherein the first electronic element is electrically connected to the circuit structure;
forming a first packaging layer on the circuit structure, wherein the first electronic element is covered by the first packaging layer;
forming at least one conductive column in the first packaging layer, wherein the conductive column is disposed on and electrically connected to the circuit structure, and a portion of the conductive column is protruded from the first packaging layer;
forming a second packaging layer on the first packaging layer, wherein the second packaging layer covers the portion of the conductive column protruding from the first packaging layer, and an end surface of the conductive column is exposed from the second packaging layer; and
forming a routing structure on the second packaging layer, wherein the routing structure is electrically connected to the conductive column.

9. The method of claim 8, wherein a manufacturing process of the conductive column comprises:
forming a barrier layer on the first packaging layer;
forming a through hole communicating the barrier layer and the first packaging layer, wherein the circuit structure is exposed from the through hole;
forming the conductive column in the through hole, wherein the conductive column is electrically connected to the circuit structure; and
removing the barrier layer to enable a portion of the conductive column to be protruded from the first packaging layer.

10. The method of claim 8, wherein the first electronic element and the first packaging layer are disposed on one side of the circuit structure, and at least one functional element is disposed on the other side of the circuit structure.

11. The method of claim 8, wherein the circuit structure has a first ground layer, and the routing structure has a second ground layer, wherein the first ground layer and the second ground layer are electrically connected to the conductive column.

12. The method of claim 8, wherein the first packaging layer and the second packaging layer are made with a same material.

13. The method of claim 8, wherein the first packaging layer and the second packaging layer are made with different materials.

14. The method of claim 8, wherein the first packaging layer has a hardness different from a hardness of the second packaging layer.

15. The method of claim 8, further comprising disposing at least one second electronic element on the routing structure, wherein the second electronic element is electrically connected to the routing structure.
